(19) United States
(12) Patent Application Publication
(10) Pub. No.: US 2008/0088323 A1
(43) Pub. Date: Apr. 17, 2008

(54) Control and method for a capacitive sensor system

(75) Inventors: Steven J. Vornsand, Lake In The Hills, IL (US); Douglas A. Williams, Elgin, IL (US)

Correspondence Address: HARNESS, DICKEY & PIERCE, P.L.C., P.O. BOX 828, BLOOMFIELD HILLS, MI, 48303, US

(73) Assignee: Emerson Electric Co., St. Louis, MO (US)

(21) Appl. No.: 11/581,796

(22) Filed: Oct. 16, 2006

(51) Int. Cl. G01R 27/26

(52) U.S. Cl. 324/686

(57) ABSTRACT

A control and method for an e-field sensor touch switch system includes an output having a first output voltage based on a static capacitance sensed by an e-field sensor and a gain module that generates a final output voltage based on amplifying a difference between an offset voltage and the first output voltage.

### FIELD

The present disclosure relates generally to capacitive sensor systems, and more particularly to electric field (e-field) sensor touch switch systems, and specifically to a control and method for a closed-loop, variable offset adjustment of the e-field sensor touch switch system.

### BACKGROUND

Modern consumer products, including household appliances, are often operated or controlled by electronic control devices. Examples of such control devices are an embedded system, a controller, a microcontroller, a computing device, and other similar devices. These control devices generally include a combination of electronic hardware and computer software which, in combination, control the functions and operation of the appliance.

One aspect of an appliance's function and operation, among others that are controlled by an electronic control device, is the user input interface to the appliance. In this regard, it is not uncommon for a household appliance to employ input devices such as buttons, knobs, switches or keypads through which a user/operator can manipulate the appliance's function and operation by providing commands, settings, or other inputs to the appliance. One well-known input device used in modern electronically-controlled appliances is an electric field (e-field) capacitive touch switch system.

E-field capacitive touch switch systems often employ several e-field touch sensor circuits each, for example, associated with an individual input button or key of the user interface. The e-field touch sensor circuits detect capacitance, which changes when a user accesses an input button or key. Consequently, a change in the capacitance detected by the e-field sensor circuit indicates that an input has been received from the user.

However, it is not uncommon that e-field capacitive touch switch systems provide false indications of a user input. This can result, for example, from external conditions to which the user interface is exposed that cause unintended and undesirable changes in capacitance. Dirt or debris (food or spills, for example) within the proximity of the user input keys may cause changes in the capacitance that are detected by the e-field touch sensor circuits which, in turn, may lead to improper operation of the system.

Additionally, the capacitance detected by each of the e-field touch sensor circuits is subject to errors arising from anticipated deviations, such as variances of element values and board layouts within a device, as well various conditions under which the system operates. As a result, any signal processing based upon outputs from the e-field touch sensor circuits should be compensated in order to avoid improper operation of the system.

Therefore, it is desirable to provide a control and method for an e-field sensor touch switch system that is operable to compensate individual e-field touch sensor circuits for deviations or errors that arise during normal operation of the system.

### SUMMARY

A control and method for an e-field sensor touch switch system includes an output having a first output voltage based on a static capacitance sensed by an e-field sensor and a gain module that generates a final output voltage based on amplifying a difference between an offset voltage and the first output voltage.

In other features, the control further comprises an offset module that adjusts the offset voltage based on the final output voltage and a reference voltage. The gain module transmits the final output voltage to a microcontroller module, the microcontroller module generates a digital response based on the final output voltage. The offset module receives a digital-to-analog signal (Sd/a) corresponding to the digital response. The microcontroller module generates a digital-to-analog signal based on the digital response using a digital-to-analog conversion scheme.

In other features, the control further comprises an e-field module that communicates with the e-field sensor and generates the first output voltage. The first output voltage is further based on an input capacitance and the microcontroller module controls the appliance based on the first output voltage. The control further comprises an e-field input line that detects a second static capacitance and indicates that the e-field sensor module is operational based on the second static capacitance.

In other features, the control further comprises a first reference e-field sensor having a fixed capacitance and a second reference e-field sensor having a capacitance substantially higher than a sum of the static capacitance and the input capacitance, the microcontroller module detects a fault based on at least one of the first reference e-field sensor and the second reference e-field sensor. The e-field module selects the e-field sensor among a plurality of e-field sensors based on a selection signal generated by the microcontroller module.

A control system for an e-field sensor touch switch system includes at least one e-field sensor that senses capacitance, a control module that selectively generates an offset voltage for the at least one e-field sensor based on the capacitance, and an output having a final voltage based on the offset voltage and a first output voltage. The control module controls the appliance based on the final voltage.

Further areas of applicability of the present disclosure will become apparent from the detailed description provided hereinafter. It should be understood that the detailed description and specific examples, while indicating the preferred embodiment of the disclosure, are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a diagram of an exemplary control module residing in an oven in accordance with the present invention;

FIG. 2 is a functional block diagram depicting a control module in accordance with the present invention;

FIG. 3 is a functional block diagram of an electric field module in accordance with the present invention; and

FIG. 4 is a flow chart illustrating the flow of a control and method for an electric field sensor touch switch system in accordance with the present invention.

### DETAILED DESCRIPTION

The following description is merely exemplary in nature and is in no way intended to limit the disclosure, its application, or uses. For purposes of clarity, the same reference numbers are used in the drawings to identify similar elements. As used herein, the term module, circuit and/or device refers to an Application Specific Integrated Circuit (ASIC), an electronic circuit, a processor (shared, dedicated, or group) and memory that execute one or more software or firmware programs, a combinational logic circuit, and/or other suitable components that provide the described functionality. As used herein, the phrase at least one of A, B, and C should be construed to mean a logical (A or B or C), using a non-exclusive logical or. It should be understood that steps within a method may be executed in different order without altering the principles of the present disclosure.

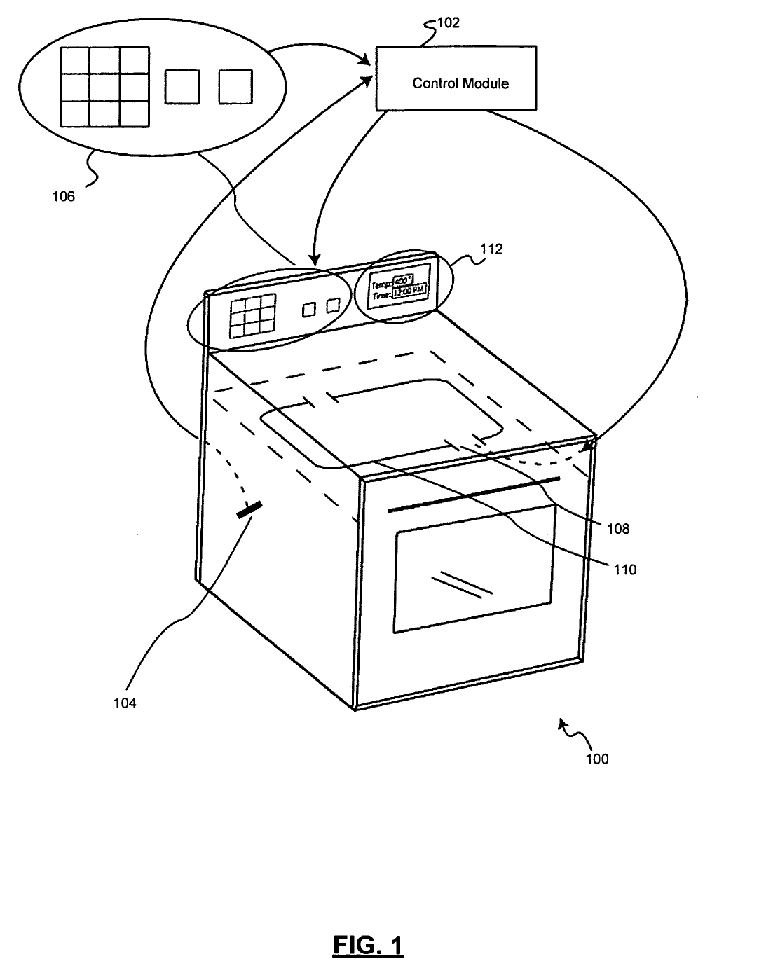

FIG. 1 illustrates an oven 100 that implements the control and method the e-field sensor touch switch system of the present disclosure. While FIG. 1 is a specific implementation of the disclosure in an oven 100, it is understood that the invention can be used for any appliance or consumer electronic device that employs a capacitive sensor system, and that the drawings and depictions are examples only. Those skilled in the art will appreciate that capacitive sensor systems that detect other stimuli including, but not limited to, humidity, temperature, and/or volatile compounds are contemplated by the present disclosure. Further, the identification of specific elements in this implementation is exemplary only.

In the oven 100, the control and method of the e-field sensor touch switch system is implemented with the control module 102. It is understood that the control module 102 includes internal operating RAM (not pictured), and that the control module 102 is programmed with software to operate in the manner described herein.

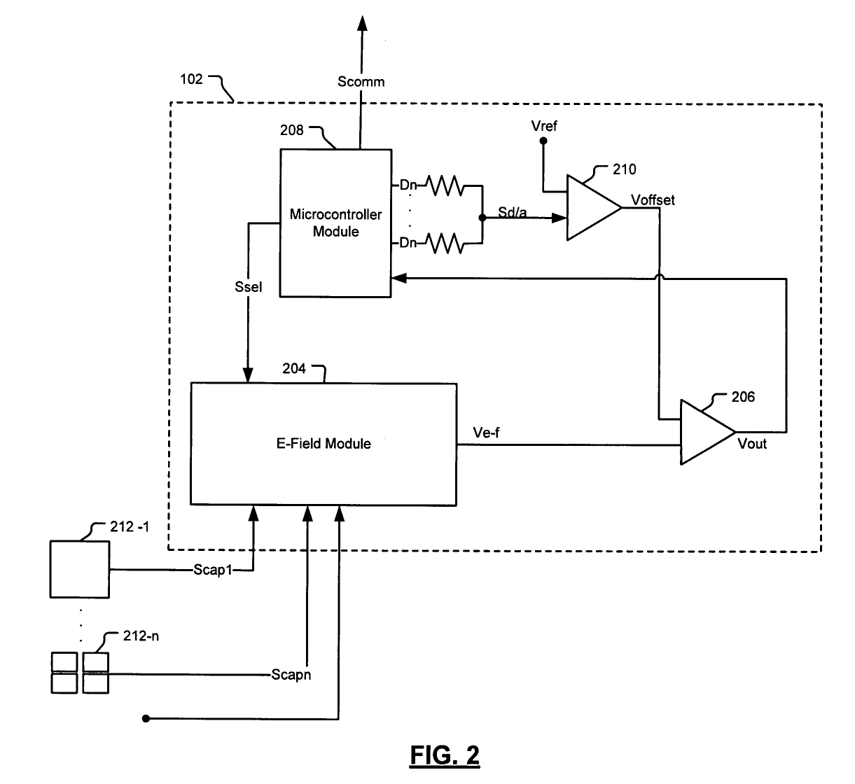

The data input for the control module 102 includes, but is not limited to, input from a temperature sensor 104, and input from user keys 106. In the present implementation, the user keys 106 serve as an input interface for electric field (e-field) sensor printed circuit boards (PCBs) depicted in FIG. 2. In the present implementation, the user keys 106 include touch pads although other implementations of the user keys 106 are contemplated.

Typically, the user keys 106 receive input (e.g. human contact) from a user/operator of the oven 100. The e-field sensor PCBs detect the presence of the input at the user input keys 106 and transmit a signal indicative of the input to the control module 102.

In this example, the user input keys 106 enable the user to select oven operations (e.g., bake or broil) and to provide other data inputs to the oven (e.g., times and temperatures). The control module 102 interprets the user inputs and controls operation of the oven accordingly.

Referring now to FIG. 2, an exemplary control module 102 that implements the control and method for the e-field sensor touch switch system is shown to include an e-field module 204, a gain module 206, a microcontroller module 208, and a variable offset module 210. E-field sensor PCBs 212-1, . . . , and 212-n, referred to collectively as the e-field sensors 212, respectively generate capacitance signals Scap1, . . . , and Scapn, referred to collectively as the capacitance signals. In other words, each of the capacitance signals indicate a capacitance value detected at the user input keys 106 depicted in FIG. 1.

The microcontroller module 208 periodically polls each of the e-field sensors 212 individually based on an address assigned to each of the e-field sensors 212. The microcontroller module 208 transmits a selection signal (Ssel) to the e-field module 204 that indicates an address value of one of the e-field sensors 212. The e-field module 204 selectively reads a capacitance signal based on the Ssel.

In the present implementation, the capacitance signals include a combination of static capacitance signals and input capacitance signals. The e-field sensors 212 generate static capacitance signals based in part on nominal static capacitance experienced by each of the e-field sensors 212 in the absence of input, or during a “non-sensing” state. Sources of the static capacitance can include, but are not limited to, stray capacitance resulting from the PCB layouts, proximity of the e-field sensors 212 to other metals, environmental, and/or ambient conditions. Over time, changes in the operating and environmental conditions as well as the manufacture of a particular e-field sensor touch switch system can lead to the unstable operation of the control module 102. Additionally, debris and contaminants can affect the static capacitance. In some cases, the static capacitance can be affected to such an extent as to give a false indication of an input. This condition, in turn, may contribute to the improper operation of the control module 102.

The e-field sensors 212 generate the input capacitance signals based on input sensed or detected at the respective user keys 106. The input can include, but is not limited to, proximity and/or contact of a user/operator of the oven 100. In the present implementation, user/operator contact with the user key 106 is considered a desired input.

The e-field module 204 communicates with the e-field sensors 212, the gain module 206, and the microcontroller module 208. As mentioned above, the microcontroller module 208 transmits a Ssel to the e-field module 204 commanding the e-field module 204 to read a capacitance signal from one of the e-field sensors 212. The e-field module 204 generates and outputs a voltage signal (Ve-f) based on the capacitance signal received from one of the e-field sensors 212. The gain module 206 receives a variable offset voltage (Voffset) from the microcontroller module 208 and the Ve-f from the gain module 206. The Voffset is discussed in further detail below. The gain module 206 determines an absolute difference between the Ve-f and the Voffset and generates an output voltage signal (Vout) based on an amplification of the difference. For example, the present embodiment implements a gain factor of 50×. Those skilled in the art can appreciate that other gain factors are contemplated.

The gain module 206 transmits the Vout to the microcontroller module 208. The microcontroller module 208 generates command signals (Scomm) that control various appliance components based on the Vout. More specifically, the microcontroller 208 can control the oven 100 based on a magnitude of the Vout. For example, the microcontroller 208 can command and/or control components including, but not limited to, the oven relays 108 and the user display 112.

Generally while the oven 100 is operational, the control module 102 is in communication with the e-field sensors 212. Upon initialization of the control and method of the e-field sensor touch switch system, the microcontroller module 208 transmits a binary selection signal (Ssel) to the e-field module 204 to poll one of the e-field sensors 212 based on an address of the polled e-field sensor 212. The microcontroller 208 receives a Vout transmitted from the gain module 206 that corresponds to a static capacitance, or undesired input, of the polled e-field sensor 212. The microcontroller module 208 converts the Vout to a corresponding digital signal via an analog-to-digital converter (ADC) (not shown).

In the present implementation, the digital signal includes a digital value range from 0 to 1023 that corresponds to a voltage level of the Vout ranging from 0 Volts to 5 Volts, respectively. Those skilled in the art can appreciate that various other Vout values are contemplated that typically do not exceed a supply voltage of the control module 102. The microcontroller 208 generates a digital response based on the digital signal to compensate for the static capacitance of the polled e-field sensor 212. Compensating for the static capacitance enables the control module 102 to isolate any desired input capacitance signal (user/operator input) detected at the user keys 106.

For example, the microcontroller 208 may generate a digital response of 475 that corresponds to a Vout of 3.44 Volts. The Vout is based on a static capacitance of 52 pico Farads sensed at a polled e-field sensor 212. In the present implementation, the microcontroller module 208 can calibrate or bias the digital response to equate to an arbitrary target point (e.g. ⅔ or ¾ of the digital value range) for a nominal static capacitance seen at any of the e-field sensors 212 in order to maximize a dynamic control range of the control and method of the e-field sensor touch switch system. Additionally, the microcontroller module 208 can periodically increment or decrement the digital response by a fixed amount (e.g. a unit step of 1) over a time period (e.g. 1 minute) to compensate for drift resulting from operating conditions of a host appliance. For example, while operating the oven 100 for a period of several hours, various parameters of components within the control module 102 will experience drift caused by the heat generated.

In the present implementation, the microcontroller 208 employs a discrete binary resistor method by writing a 1 or “ON signal” (e.g. 5 Volts) or a 0 or “OFF signal” (e.g. 0 Volts) on each of resistors D(0), . . . , and D(n), referred to collectively as the resistors D, based on the digital response. In other words, the microcontroller module 208 determines whether to supply an ON or OFF signal to each of the resistors based on the Ve-f sensed by the e-field module 204 to compensate for the static capacitance at the polled e-field sensors 212. In the present implementation, the resistors D(0) and D(n) correspond to a lowest order bit and a highest order bit, respectively, and each of the resistors possesses a distinct impedance. For example, D(0) may have an impedance of 256,000 ohms and D(n) may have an impedance of 500 ohms. Therefore, those skilled in the art can appreciate that various binary combinations of ON and OFF signals placed on the resistors D generate various digital responses. Voltages across the resistors D are summed to generate a digital-to-analog signal (Sd/a). In various embodiments, the microcontroller module 208 can generate the Sd/a using other components and/or digital-to-analog conversion schemes including, but not limited to, pulse width modulation (PWM), a resistor ladder network, or a dedicated IC.

The variable offset module 210 communicates with the microcontroller module 208 and the gain module 206. The variable offset module 210 can include, but is not limited to, an inverting amplifier. The variable offset module 210 generates the Voffset based on the Sd/a and a reference voltage (Vref). The Voffset can be selected or programmed to equal the Vout or a voltage that leads to a fixed difference between the Voffset and the Vout, thereby indicating that no input from a user/operator of the oven 100 is present at the user keys 106.

Portions of the control module 102 may be implemented by one or more integrated circuits (IC) or computer chips. For example, the variable offset module 210 and the gain module 206 may be implemented by a single chip. Alternatively, most of the control module 102 may be implemented as a system on chip (SOC).

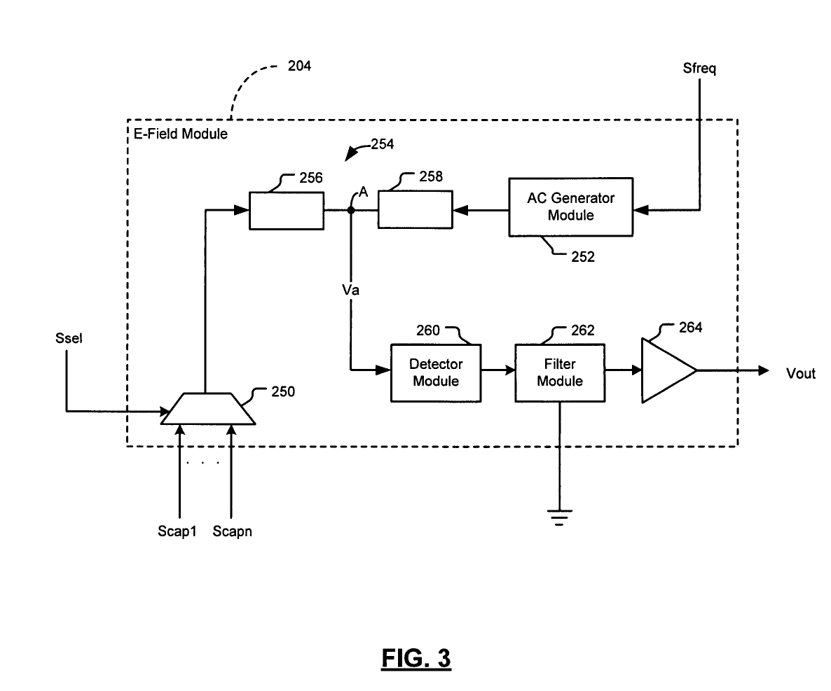

Referring now to FIG. 3, the e-field module 204 is shown in more detail. The e-field module 204 communicates with the e-field sensors 212, the gain module 206, and the microcontroller module 208 as described in FIG. 2. The e-field module 204 includes a multiplexer 250, an alternating current (AC) generator module 252, a fixed impedance divider 254, a detector module 260, a filter module 262, and a compensation module 264.

The multiplexer 250 receives the Ssel from the microcontroller module 208 depicted in FIG. 2 and selects one of the capacitance signals that respectively corresponds to one of the e-field sensors 212. The AC generator module 252 generates an AC signal internal to the e-field module 204 that is transmitted through the fixed impedance divider 254. The AC signal can include, but is not limited to, a low frequency sine wave having minimal harmonic content. The fixed impedance divider 254 includes impedance elements 256 and 258, referred to collectively as the impedance elements. In the present implementation, one of the impedance elements embodies an impedance of the polled e-field sensor 212.

The detector module 260 rectifies a voltage (Va) at a node A. The filter module 262 filters signal disturbances or interference and transmits the Va to the compensation module 264. The compensation module 264 supplies gain and offset compensation to the Va internal to the e-field module 204 and outputs the Vout. In other words, during operation of the control and method for the e-field sensor touch switch system, the e-field module 204 generates a voltage corresponding to a static capacitance signal sensed at one of the e-field sensors 212.

In various embodiments, the control module 102 may include an e-field input line (not shown) that is electrically connected to the e-field module 204 but lacks a connection to an e-field sensor 212. The e-field input line solely senses the presence of static capacitance thereby ensuring that the e-field module 204 is operational when the e-field module 204 is able to read a capacitance signal from the e-field input line. Additionally, the control module 102 can verify the operation of the e-field sensors 212 by using the capacitance signal of the e-field input line as a reference point.

In various other embodiments, the control module 102 may include an e-field input line (nominal input line) having a fixed capacitance that remains stable during varying temperatures that represents a nominal static capacitance and another e-field input line (threshold input line) having a capacitance substantially higher than the e-field sensors 212 that sense input. These nominal and threshold input lines are used as references to enable the control module 102 to detect a fault condition. For example, if the e-field module 204 receives a capacitance signal from an e-field sensor 212 that exceeds the threshold input line, a fault may have occurred.

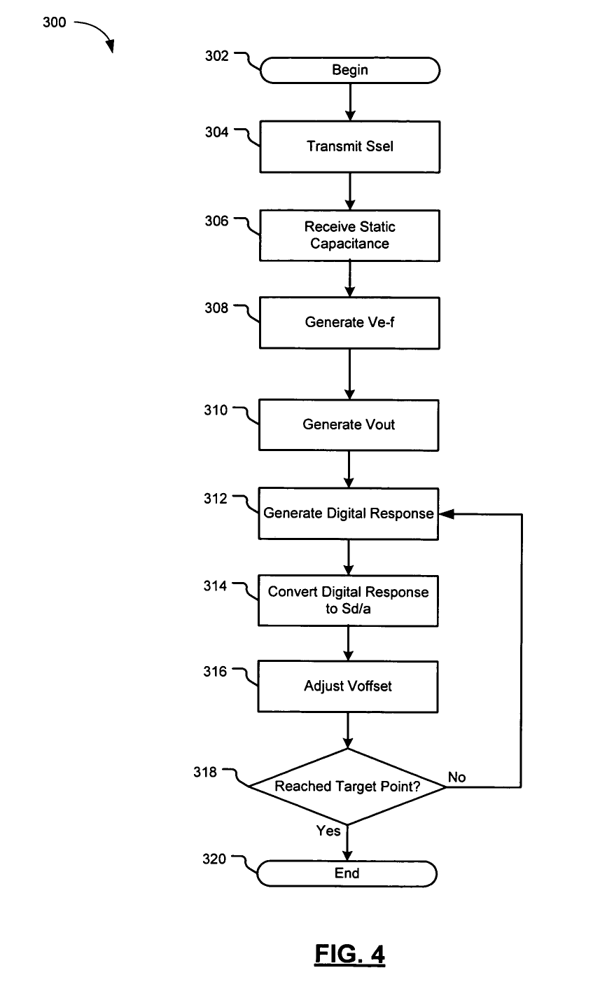

Referring now to FIG. 4, a method 300 for operating the control method for the e-field sensor touch switch system is shown in more detail. The method 300 begins at step 302. In step 304, the microcontroller module 208 transmits a Ssel to the e-field module 204. In step 306, the e-field module 204 selects one of the e-field sensors 212 based on the Ssel and receives a capacitance signal corresponding to a static capacitance at the polled e-field sensor 212.

In step 308, the e-field module 204 generates a Ve-f based on the capacitance signal. In step 310, the gain module 206 generates a Vout based on amplifying an absolute difference between the Ve-f and a Voffset. In step 312, the microcontroller module 208 generates a digital response based on the Vout. In step 314, the digital response is converted to a Sd/a and transmitted to the variable offset module 210.

In step 316, the variable offset module 210 adjusts the Voffset based on an difference between the Sd/a and a reference voltage (Vref). In step 318, the microcontroller module 208 determines whether the digital response has reached the target point. If the digital response has not reached the target point, the microcontroller module 208 returns to step 312. If the digital response has reached the target point, the microcontroller module 208 proceeds to step 320. In step 320, the method 300 ends.

Those skilled in the art can now appreciate from the foregoing description that the broad teachings of the disclosure can be implemented in a variety of forms. Therefore, while this disclosure includes particular examples, the true scope of the disclosure should not be so limited since other modifications will become apparent to the skilled practitioner upon a study of the drawings, the specification and the following claims.

What is claimed is:

1. An e-field sensor touch switch control system comprising:
an output having a first output voltage based on a static capacitance sensed by an e-field sensor; and
a gain module that generates a final output voltage based on amplifying a difference between an offset voltage and said first output voltage.

2. The control system of claim 1 further comprising an offset module that adjusts said offset voltage based on said final output voltage and a reference voltage.

3. The control system of claim 1 wherein said gain module transmits said final output voltage to a microcontroller module, said microcontroller module generates a digital response based on said final output voltage.

4. The control system of claim 3 wherein said offset module receives a digital-to-analog signal (Sd/a) corresponding to said digital response.

5. The control system of claim 3 wherein said microcontroller module generates a digital-to-analog voltage signal based on said digital response.

6. The control system of claim 5 wherein said microcontroller module generates said digital-to-analog voltage signal using one of a discrete binary resistor method, a resistor ladder network, and pulse width modulation.

7. The control system of claim 3 further comprising an e-field module that communicates with said e-field sensor and generates said first output voltage.

8. The control system of claim 7 wherein said first output voltage is further based on an input capacitance and said microcontroller module controls the appliance based on said first output voltage.

9. The control system of claim 7 further comprising an e-field input line that detects a second static capacitance and indicates that said e-field sensor module is operational based on said second static capacitance.

10. The control system of claim 8 wherein further comprising a first reference e-field sensor having a fixed capacitance and a second reference e-field sensor having a capacitance substantially higher than a sum of said static capacitance and said input capacitance, said microcontroller module detects a fault based on at least one of said first reference e-field sensor and said second reference e-field sensor.

11. The control system of claim 7 wherein said e-field module selects said e-field sensor among a plurality of e-field sensors based on a selection signal generated by said microcontroller module.

12. A control method for an e-field sensor touch switch system comprising:
generating a first output voltage based on a static capacitance sensed by an e-field sensor; and
generating a final output voltage based on amplifying a difference between an offset voltage and said first output voltage.

13. The control method of claim 12 further comprising adjusting said offset voltage based on said final output voltage and a reference voltage.

14. The control method of claim 12 further comprising generating a digital response based on said final output voltage.

15. The control method of claim 14 further comprising generating a digital-to-analog voltage signal based on said digital response.

16. The control method of claim 15 further comprising generating said digital-to-analog voltage signal using one of a discrete binary resistor method, a resistor ladder network, and pulse width modulation.

17. The control method of claim 12 further comprising generating a first output voltage further based on an input capacitance, and a microcontroller module controls the appliance based on said first output voltage.

18. The control method of claim 17 further comprising communicating that an e-field module is operational by detecting a second static capacitance on an e-field input line.

19. The control method of claim 17 further comprising detecting a fault based on at least one of a first reference e-field sensor having a fixed capacitance and a second reference e-field sensor having a capacitance substantially higher than a sum of said static capacitance and said input capacitance.

20. The control method of claim 18 further comprising selecting said e-field sensor among a plurality of e-field sensors based on a selection signal generated by said microcontroller module.

21. A control system for an e-field sensor touch switch system comprising:
at least one e-field sensor that senses capacitance;
a control module that selectively generates an offset voltage for said at least one e-field sensor based on said capacitance; and
an output having a final voltage based on said offset voltage and a first output voltage, wherein said control module controls the appliance based on said final voltage.
